(19) United States
(12) Patent Application Publication
(10) Pub. No.: US 2026/0073109 A1
(43) Pub. Date: Mar. 12, 2026

(54) VHDL-BASED SEMI-AUTOMATIC SIMULATION METHOD AND SYSTEM FOR SOFTWARE REQUIREMENTS OF COMPLEX EMBEDDED SYSTEM

(71) Applicant: Peking University, Beijing (CN)

(72) Inventor: Zhi JIN, Beijing (CN)

(73) Assignee: Peking University, Beijing (CN)

(21) Appl. No.: 19/322,273

(22) Filed: Sep. 8, 2025

(30) Foreign Application Priority Data
Sep. 6, 2024 (CN) 202411247176.7

(51) Int. Cl. G06F 30/3308; G06F 8/10

(52) U.S. Cl. CPC G06F 30/3308; G06F 8/10

(57) ABSTRACT

A VHDL-based semi-automatic simulation method and system for software requirements of a complex embedded system are provided, relating to the field of requirements engineering. The method includes: pre-defining a domain-specific device model; generating an atomic controller VHDL model and a data storage VHDL according to atomic controller requirements in a software requirements specification; generating a composite controller VHDL model according to composite controller requirements in the software requirements specification; at a phase of system integration, combining the atomic controller VHDL model, a device VHDL model, the data storage VHDL model and the composite controller VHDL model to obtain a complete system model; at a phase of property verification, performing property verification on the complete system model by using a VHDL verification tool Vivado. VHDL models meeting the requirements can be generated and combined to obtain a complete system model, thereby achieving requirement simulation and property verification.

### CROSS-REFERENCE TO RELATED APPLICATION

This patent application claims the benefit and priority of Chinese Patent Application No. 202411247176.7 filed with the China National Intellectual Property Administration on Sep. 6, 2024, the disclosure of which is incorporated by reference herein in its entirety as part of the present application.

### TECHNICAL FIELD

The present disclosure relates to the technical field of requirements engineering, and in particular to, a Very-High-Speed Integrated Circuit Hardware Description Language (VHDL)-based semi-automatic simulation method and system for software requirements of a complex embedded system.

### BACKGROUND

With the development of embedded systems, the scale and complexity of the system increase exponentially. These systems involve multiple components, network communication, parallel processing, real-time response and other complex characteristics. The conventional requirement verification method cannot effectively cope with this complexity, so a simulation method is required to provide more comprehensive and accurate verification.

During the development of complex embedded systems, requirement errors or omissions may lead to serious consequences, such as system failure, incomplete functions, and performance problems. The repair cost of these consequences is often expensive. The issues can be found and addressed early through simulation verification in the requirement phase, thereby reducing the risk and cost in the development process. In addition, development of the complex embedded system is inherently an iterative and refinement-driven process. That is, some vague or imperfect parts that may exist in the requirements specification need to be verified and improved through simulation. With continuous simulation verification and improvement, the quality of requirements specification and the reliability of the system can be gradually improved.

Therefore, how to provide a requirements simulation method for a complex embedded system is a technical problem that needs to be solved urgently by those skilled in the art.

### SUMMARY

In view of this, the present disclosure provides a VHDL-based semi-automatic simulation method and system for software requirements of a complex embedded system, which can solve the problems in the background.

To achieve the objective above, the present disclosure employs following technical solution.

A VHDL-based semi-automatic simulation method for software requirements of a complex embedded system includes the following steps:
pre-defining a domain-specific device model, where the device model is a manually constructed device VHDL model;
generating an atomic controller VHDL model according to atomic controller requirements in a software requirements specification, and manually supplementing and improving computing components in the atomic controller VHDL model;
generating a data storage VHDL model according to the atomic controller requirements in the software requirements specification;
generating a composite controller VHDL model according to composite controller requirements in the software requirements specification;
at a phase of system combination, combining the atomic controller VHDL model, the device VHDL model, the data storage VHDL model and the composite controller VHDL model generated, to obtain a complete system model; and
at a phase of property verification, performing property verification on the complete system model by using a VHDL verification tool Vivado.

In an embodiment, generating the atomic controller VHDL model and manually supplementing and improving the computing components include the following steps:
traversing the atomic controller requirements in the software requirements specification to obtain names of atomic controllers, the computing components, devices and data storages involved in the atomic controller requirements;
generating a model structure of the atomic controller VHDL model according to names of the atomic controllers and names of the computing components in the atomic controller requirements;
generating an entity port declaration of the atomic controller VHDL model according to the names of the devices and call signals to the devices involved in the atomic controller requirements, the names of the data storages and call signals to the data storages involved in the atomic controller requirements, and the names of the computing components and call signals to the computing components involved in the atomic controller requirements;
generating an initial state and an end state of the atomic controller VHDL model based on a relationship between the atomic controller requirements and the composite controller requirements, and generating a state machine process of the atomic controller by combining a sequence of call signals of the atomic controller requirement to the device, to the data storage and to the computing component;
generating signals and variables used in the atomic controller VHDL model according to a description of shared phenomena in the atomic controller requirement; and
manually supplementing and improving the computing components in the generated atomic controller VHDL model.

In an embodiment, generating the data storage VHDL model includes:
generating an entity port declaration of the data storage VHDL model according to the names of the data storages and the call signals to the data storages involved in the atomic controller requirements.

In an embodiment, generating the composite controller VHDL model includes the following steps:
generating an entity port declaration of the composite controller VHDL model according to the name of the composite controller in the composite controller requirements;
generating a state of the composite controller VHDL model according to names of the composite controllers and a relationship thereof in the composite controller requirements; and
generating a transition condition between corresponding states according to a temporal constraint on the composite controller in the composite controller requirements.

In an embodiment, obtaining a complete system comprises following steps:
generating a system structure tree according to the names of the composite controllers in the composite controller requirements and a relationship of the composite controllers, and traversing the structure tree from bottom to top to combine the composite controller VHDL model and the atomic controller VHDL model;
combining a model obtained by combining in a previous step with the data storage VHDL model according to the names of the data storages and the call signals to the data storages involved in the atomic controller requirements; and
combining the model obtained by combining in a previous step with the device VHDL model according to the names of the devices and the call signals to the devices involved in the atomic controller requirements, to obtain the complete system model.

In an embodiment, at phase of property verification, a property type to be verified and a property capable of being verified by Vivado include:
for correctness of data flow, verifying whether the system meets a data correctness requirement defined in the software requirements specification when processing data;
for correctness of control flow, verifying whether the system operates according to a function of the software requirements specification; and
for satisfiability of temporal constraint, verifying whether a complex embedded system with a temporal constraint completes a corresponding action within a specified time.

In an embodiment, the verification of satisfiability of temporal constraint includes following three main types:
(1) verifying entry into a state X at a specific time to: A< >X imply t==t₀;
(2) with a task T as a periodic task of a period of p, assuming that a clock t is specifically used to record an execution time of the task, verifying whether the execution time meets the period: A< >Tinit imply t==p, where T.init represents an init state node of a timed automaton model T; and
(3) verifying whether a time interval in which the state X is maintained is [t₁, t₂]: A< >X imply t>=t₁&&t<=t₂.

A VHDL-based semi-automatic simulation system for software requirements of a complex embedded system includes a device predefining module, an atomic controller generation module, a data storage generation module, a composite controller generation module, a system combination module, and a property verification module.

The device predefining module is configured to pre-define a domain-specific device model, where the device model is a manually constructed device VHDL model.

The atomic controller generation module is configured to generate an atomic controller VHDL model according to atomic controller requirements in a software requirements specification, and manually supplement and improve a computing component in the atomic controller VHDL model.

The data storage generation module is configured to generate a data storage VHDL model according to the atomic controller requirements in the software requirements specification.

The composite controller generation module is configured to generate a composite controller VHDL model according to composite controller requirements in the software requirements specification.

The system combination module is configured to combine the atomic controller VHDL model, the device VHDL model, the data storage VHDL model and composite controller VHDL model generated, to obtain a complete system model.

The property verification module is configured to perform property verification on the complete system model by using a VHDL verification tool Vivado.

According to the foregoing technical solution, compared with the prior art, the present disclosure provides a VHDL-based semi-automatic simulation method and system for software requirements of a complex embedded system. Generated atomic controller VHDL model, device VHDL model, data storage VHDL model and composite controller VHDL model are combined to obtain a complete system model, and a semi-automatic generation process of the simulation model can be achieved. Then, Vivado software is called for property verification, thereby achieving semi-automatic generation and property verification of a requirement simulation model.

### BRIEF DESCRIPTION OF THE DRAWINGS

To describe the technical solutions of embodiments of the present disclosure or in the prior art more clearly, the following briefly introduces the accompanying drawings required for describing the embodiments or the prior art. Apparently, the accompanying drawings in the following description show merely some embodiments of the present disclosure, and those of ordinary skill in the art may still derive other drawings from these accompanying drawings without creative efforts.

FIG. 1 is a flowchart of a VHDL-based semi-automatic simulation method for software requirements of a complex embedded system according to the present disclosure;

FIG. 2 is a VHDL model structure corresponding to a basic structure in atomic controller requirement according to the present disclosure;

FIG. 3A to FIG. 3C are diagrams of a gyroscope device model, a sun sensor device model and a thruster device model according to the present disclosure;

FIG. 4A to FIG. 4D are diagrams of a device declaration, comprehensive composite controller requirement, data acquisition composite controller requirement and gyroscope data acquisition atomic controller requirement in a software requirements specification of a sun search system according to the present disclosure;

FIG. 5 is a generated comprehensive composite controller model of a sun search system according to the present disclosure;

FIG. 6 is a generated data acquisition composite controller model of a sun search system according to the present disclosure;

FIG. 7 is a generated gyroscope data acquisition atomic controller model of a sun search system according to the present disclosure;

FIG. 8 is a generated system structure tree of a sun search system according to the present disclosure;

FIG. 9 is a simulation waveform diagram of a gyroscope data acquisition atomic problem of a sun search system by using Vivado platform according to the present disclosure.

### DETAILED DESCRIPTION OF THE EMBODIMENTS

The technical solutions of the embodiments of the present disclosure are clearly and completely described below with reference to the accompanying drawings in the embodiments of the present disclosure. Apparently, the described embodiments are merely some rather than all of the embodiments of the present disclosure. All other embodiments obtained by those of ordinary skill in the art based on the embodiments of the present disclosure without creative efforts shall fall within the protection scope of the present disclosure.

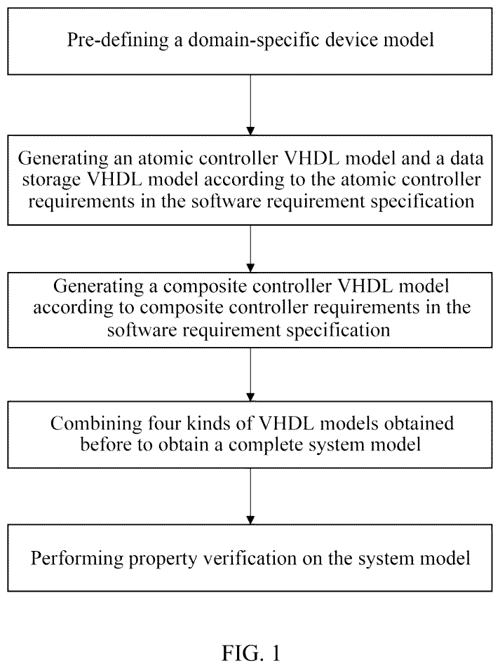

An embodiment of the present disclosure provides a VHDL-based semi-automatic simulation method for software requirements of a complex embedded system, as shown in FIG. 1, including the following steps:

1. A domain-specific device VHDL model is generated according to atomic controller requirements in a software requirements specification.

Specifically, the devices are generally classified into sensors and actuators, which play different roles and have different functions in a system. A sensor is a device for sensing an external environment, which can detect various physical quantities or parameters in the environment, periodically or in response to a trigger by external events, and transmit the detected data to the system. An actuator is a device for executing a corresponding behavior according to a system instruction, which can execute a specified operation or action according to a received control signal. In the VHDL model, various state transitions are achieved through state machine process, including basic on and off states, and an external event can be simulated through a port.

2. An atomic controller VHDL model is generated according to the atomic controller requirements in the software requirements specification.

The atomic controller requirements in the software requirements specification are traversed to obtain names of atomic controllers, computing components, devices and data storages involved in the atomic controller requirements. A model structure of the atomic controller VHDL model is generated according to the names of the atomic controllers and the names of the computing components in the atomic controller requirements. An entity port declaration of the atomic controller VHDL model is generated according to the names of the devices involved in the atomic controller requirement, call signals of the atomic controller requirements to the devices, the data storage names involved in the atomic controller requirements, call signals of the atomic controller requirements to the data storages, the names of the computing components involved in the atomic controller requirements and call signals of the atomic controller requirements to the computing components. An initial state and an end state of the atomic controller VHDL model are generated based on a relationship between the atomic controller requirements and the composite controller requirements to cope with calling to the composite controllers, and the state machine process of the atomic controller is generated by combining a sequence of the call signals of the atomic controller requirements to the devices, the data storages and the computing components. Signals and variables used in the atomic controller VHDL model are generated according to a description of shared phenomena in the atomic controller requirements; and the computing components in the generated atomic controller VHDL model are supplemented and improved manually.

Specifically, the atomic controller model is generated according to the atomic controller requirements in the software requirements specification. The atomic controllers are called by the composite controllers, or are not called to run in parallel with other controllers.

Problem domains, such as the controllers, the computing components and the data storages involved in the atomic controller requirement, belong to internal architectural elements of the embedded software system. In a design of an atomic controller VHDL simulation model, the controllers, the computing components and the data storages are all mapped to a VHDL design entity. However, as the data storages manifest a correlation between sub-requirements, the same data storage may occur in multiple atomic controller requirements, so the atomic controller VHDL model does not include the data storages. Due to a unique requirement mode of data transformation, all atomic problems are divided into three categories: the first is an atomic problem without calculation, the second is an atomic problem about self-defined data transformation component, and the third is other atomic problems about interacting with self-defined components. Therefore, the atomic controller VHDL model only contains a controller and a computing component, where the computing component is not necessary. A model structure of the atomic controller VHDL model is generated according to the names of the atomic controllers and the names of the computing components in the atomic controller requirements.

The VHDL design entity includes an entity and an architecture. The entity defines an interface of the VHDL design entity, including names, data types and directions of input and output signals. The architecture defines a specific implementation of the VHDL design entity, such as, describing a logic relationship between components, signal assignment and temporal relationship. A behavior interaction between the controller and each problem domain in a problem graph is mapped to a port in the entity. A behavior interaction portion according to the atomic controller requirements is converted into an entity port declaration in the atomic controller VHDL model. A behavior interaction type in the behavior interaction of the atomic controller is converted into a data type of the entity port declaration in the model according to Table 1.

TABLE 1
Relationship Table about Conversion from Behavior Interaction
of Atomic Controllers to Entity Port Declaration

| | Behavior | |
|---|---|---|
| | interaction | |
| Port | type | Data type of port declaration |
| Fixed port | — | “STD_LOGIC” data type in port declaration |
| | | of VHDL model |
| Generation | Value/state/ | “STD_LOGIC_VECTOR (31 downto 0)” |
| port | event | data type in port declaration of VHDL model |
| | Instruction | “STD_LOGIC” data type in port declaration |
| | | of VHDL model |

An initial state and an end state of the atomic controller VHDL model are generated based on the relationship between the atomic controller requirements and the composite controller requirements to cope with calling by the composite controller. In the initial state, an operating state signal is done=‘0’, indicating that the atomic controller VHDL model does not operate; when a starting operation signal start=‘1’, the state is transitioned to the operating state, and the atomic controller VHDL model starts to operate. In the end state, the operating state signal is done=‘1’, indicating that the atomic controller VHDL model has completed the operation, and the state is transitioned to the initial state. An operating state of the atomic controller VHDL model is generated according to a sequence of call signals of the atomic controller requirements to the devices, the data storages and the computing components.

One memory RAM (Random-access memory) and a storage process (Process) are declared for each input port according to the behavior interaction in the atomic controller requirement.

3. A data storage VHDL model is generated according to the atomic controller requirements in the software requirements specification.

An entity port declaration of the data storage VHDL model is generated according to the names of the data storages and the call signals to the data storages involved in the atomic controller requirements and the call signal of the atomic controller requirement to the data storage, and an architecture declaration in the generated data storage VHDL model is supplemented and improved manually.

4. A composite controller VHDL model is generated according to composite controller requirements in the software requirements specification.

An entity port declaration of the composite controller VHDL model is generated according to names of composite controllers in the composite controller requirements; a state of the composite controller VHDL model is generated according to names of the composite controllers and a relationship thereof in the composite controller requirements to cope with the calling by other composite controllers on it; a transition condition between corresponding states is generated according to a temporal constraint on the composite controllers in the composite controller requirements; and an architecture declaration in the generated composite controller VHDL model is supplemented and improved manually.

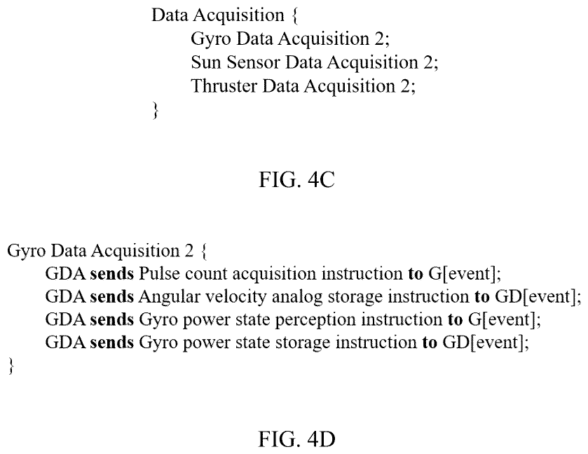

Specifically, a format of the software requirements specification is as follows. The software requirements specification is a structured representation, which mainly includes problem domain declaration, composite controller software requirements and atomic controller software requirements. The problem domain declaration is a description of different problem domain types, as shown in FIG. 4A, a declaration of the problem domain of a sun search system is provided. The problem domain is divided into a lexical domain and a causal domain. The lexical domain is used for data storage, for example, after a data acquisition function is completed, the collected data is sent to the lexical domain for storage. The causal domain indicates that there is a causal relationship between interactions, and taking a gyroscope device as an example, if a turn-on command is received, the gyroscope device is in an on state.

The composite controller is divided into a comprehensive composite controller without a calling request (specified as shown in FIG. 4B) and a composite controller with a calling request (specified as shown in FIG. 4C). The composite controller describes a combination relationship of the atomic controller or some composite controllers, including a sequential structure, a loop structure, a branch structure and a parallel structure. In addition, a syntactic specification for the temporal constraint is defined.

In the atomic controller, various structures for the software behavior interaction are defined, such as a sequential structure, a loop structure, a branch structure and a parallel structure. In addition, a syntactic specification for the temporal constraint is also defined, as shown in FIG. 2. The sequential structure is segmented by semicolon “;”, b represents a behavior interaction, a format of which is generally “Controlname sends/receives instruction/data to anotherControlname/Device [event/value/state]”, and the sequential structure refers to executing various behavior interactions in sequence. The branch structure is embodied as “if (b1constraint) { . . . } else if (b2constraint) { . . . } . . . ”, b1constraint and b2constraint are constraint conditions for executing related interactions by branches. In addition, the branch structure may have multiple branches, and missing branches can be automatically generated according to the constraint conditions when the model is generated. The loop structure is embodied as “while (brelated) { . . . }”, brelated is a constraint condition of loop execution, which is generally a constraint condition on a clock of a certain behavior interaction b. The parallel structure is represented by a symbol “|”. As various models in a timed automaton model are parallel, there is no need to perform additional processing on the parallel structure. The temporal constraint structure has two structures, where “b1; after (T); b2” represents time delay, that is, after the execution of the behavior interaction b1, there is a pause for time T followed by the execution of a behavior interaction b2; and “at(T){b}” represents that the behavior interaction b is triggered at time T.

The following describes how to generate the composite controller VHDL model. The composite controller calls other composite controllers or the atomic controllers to implement the function. To acquire a calling relationship between the composite controllers and the atomic controllers, a system structure tree is constructed according to the composite controller requirements in the software requirements specification, all non-leaf nodes in the structure tree are composite controllers, and child nodes of a non-leaf node are the atomic controllers and the composite controllers called by a composite controller.

Then, how to obtain a state and transition from the software requirement specification is studied from the calling relationship. Prior to this, for each composite controller VHDL model, the initial state and the end state are established to cope with the calling of other composite controllers. In the initial state, an operating state signal is done=‘0’, indicating that the composite controller VHDL model does not operate; when a starting operation signal start=‘1’, the state is transitioned to the operating state, and the composite controller VHDL model starts to operate. In the end state, an operating state signal is done=‘1’, indicating that the composite controller VHDL model has completed the operation, and the state is transitioned to the initial state. An operating state of the composite controller VHDL model is generated according to a calling relationship between the composite controller and other controllers.

A relationship structure between other controllers called by the composite controller is different, so a method for transforming to a VHDL model is also different, which is specifically as follows.

For a parallel structure, a new operating state is created first, and the number of call signals included in the operating state is determined according to the number of controllers included in the parallel structure. The call signal is named with the name of the composite controller to be called plus a field “_start” to form “Controlname_start”, and then a transition from this state to the next state and a synchronization signal in a transition constraint are added to form “Controlname_done”.

For a sequential structure, a new operating state is created first, where the operating state includes one call signal, and the call signal “Controlname_start” is named with the name of the composite controller to be called plus the field “start”, then a transition from this state to the next state and a synchronization signal “Controlname_done” in the transition constraint are added.

For a branch structure, a start state of the branch is marked, and then the transition is established from this state for each branch, and a guard condition generated according to the branch condition is added to the transition. For a relationship structure in the branch, a corresponding model structure is generated according to its structure type. After all branches are processed, it is necessary to determine whether all branches cover all possibilities, and if not, a new branch needs to be generated to deal with other conditions. Finally, a new operating state “end” is added to indicate an end state of the branch structure, and a transition from the last state of each branch to the state “end” is established.

For a loop structure, a loop start state is marked at first, and then a corresponding model structure is generated for an interaction content in the loop structure according to its structure, and a transition back to the loop start state is added, where a guard condition generated according to the loop condition is added on the transition constraint.

For temporal constraint “after (T)”, an invariant “t<=T” is added at a current state, an update constraint “t=0” is added to a transition entering the current state, and a security constraint “t>=T” is added to a transition leaving the current state, where t is a clock variable of a current model.

For temporal constraint “at(T){b}”, two new operating states are created at first, the first operating state is used for entering when a previous operating state satisfies a transition condition, and a transition from this state to the next new operating state (i.e., the other operating state among the two new operating states, excluding the first operating state) is added, and a guard condition “t==T” is added on the transition, where t is a clock variable of the current model.

5. At a phase of system combination, the generated atomic controller VHDL model, device VHDL model, data storage VHDL model and composite controller VHDL model are combined to obtain a complete system model.

A system structure tree is generated according to the names of the composite controllers in the composite controller requirements and a relationship thereof, the structure tree is traversed from bottom to top to combine the composite controller VHDL model and the atomic controller VHDL model. The model obtained by combining in a previous step and the data storage VHDL model are combined according to the names of the data storages and the call signals to the data storages involved in the atomic controller requirements. The model obtained by combining in a previous step and the device VHDL model are combined according to the names of devices and the call signals to the devices involved in the atomic controller requirement to obtain the complete system model.

6. At a phase of property verification, a VHDL verification tool Vivado is used to perform property verification according to different property formulation styles.

Property verification is performed after a requirement simulation model is generated, and the properties are divided into the following types for verification.

For correctness of data flow, whether the system meets a data correctness requirement defined in the software requirements specification when processing data is verified, including checking correct transfer, conversion, calculation, storage and like of the data.

For correctness of control flow, whether the system operates according to a function of the software requirements specification is verified, including checking whether the system correctly executes the required calculation, control and communication function or not.

For satisfiability of temporal constraint, whether a complex embedded system with a temporal constraint completes a corresponding action within a specified time is verified.

Specifically, the verification of satisfiability of temporal constraint includes the following three main types:
(1) verifying entry to a state X at a specific time to: A< >X imply t==t₀;
(2) with a task T as a periodic task of a period of p, assuming that a clock t is specifically used to record an execution time of the task, verifying whether the execution time of the task T meets the period: A< >T.init imply t==p, where T.init represents an init state node of a timed automaton model T; and
(3) verifying whether a time interval in which the state X is maintained is [t₁, t₂]: A< >X imply t>=t₁&&t<=t₂.

Corresponding to the method shown in FIG. 1, an embodiment of the present disclosure further provides a VHDL-based semi-automatic simulation system for software requirements of a complex embedded system, which is used for specific implementation of the method in FIG. 1. The VHDL-based semi-automatic simulation system for software requirements of a complex embedded system provided by the embodiment of the present disclosure can be applied to a computer terminal or various mobile devices, specifically including:

a device predefining module, configured to pre-define a domain-specific device model, where the device model is a manually constructed device VHDL model;
an atomic controller generation module, configured to generate an atomic controller VHDL model according to atomic controller requirements in a software requirements specification, and manually supplement and improve computing components in the atomic controller VHDL model;
a data storage generation module, configured to generate a data storage VHDL model according to the atomic controller requirements in the software requirements specification;
a composite controller generation module, configured to generate a composite controller VHDL model according to composite controller requirements in the software requirements specification;
a system combination module, configured to combine the generated atomic controller VHDL model, device VHDL model, data storage VHDL model and composite controller VHDL model to obtain a complete system model; and
a property verification module, configured to perform property verification on the complete system model by using a VHDL verification tool Vivado.

For further description of the technical solution in detail, a specific instance about a sun search system is provided below for introduction.

1. An atomic controller model is generated according to atomic controller requirements in a software requirements specification.

There are 19 atomic controller models in the sun search system. An atomic controller, named gyroscope data acquisition, is used as an example, and the software requirements specification is as shown in FIG. 4D. An initial state is firstly added, the atomic controller is called by a data acquisition composite controller, a call signal is added in the initial state, and the call signal “Gyro data Acquisition 2_start” is named with a name of a composite controller to be called plus a field “_start”. Then, an end state is added, a transition from the end state to the initial state and a synchronization signal “Gyro data Acquisition 2_done” in a transition constraint are added. Then, an interaction portion is processed according to a sequential structure shown in FIG. 2. For the interaction portion, different interaction domain types are correspondingly processed. According to the software requirements specification, an interaction with a gyroscope device model (G) is performed at first, a type of the behavior interaction is an event, then, according to the processing of a behavior interaction of a device event type in Table 1, a state is firstly added, and a transition is established. As interaction information is “sends”, a synchronization signal “Pulsecountacquisitioninstruction!” is added to the transition. Next, a behavior interaction with gyroscope data storage (GD) is performed, the type of the interaction is the event, then, according to the processing of the behavior interaction of a data storage event type in Table 1, a new state is added, a transition is established, and an update constraint “Angularvelocityanalogstorageinstruction=1” is added on the transition. All behavior interactions are processed in sequence, a transition back to the initial state is finally established, and a synchronization signal “GyroDataAcquisitionFIns!” is added, indicating that the gyroscope data acquisition is completed, and then a completion signal is sent. An ultimately generated gyroscope data acquisition atomic controller model is as shown in FIG. 7.

2. An entity port declaration of the device VHDL model is generated according to the atomic controller requirement in the software requirements specification, and a model architecture is supplemented and improved manually.

Names of all devices are obtained based on a casual domain, then behavior interactions in the atomic controller requirements are traversed. If a device is involved in a behavior interaction, the content of the behavior interaction is added with names of a sender and a receiver and then abbreviated to obtain a port name, such as “in_GDA_G_Puls_coun”, and then the port name is added to the entity port declaration of the device VHDL model.

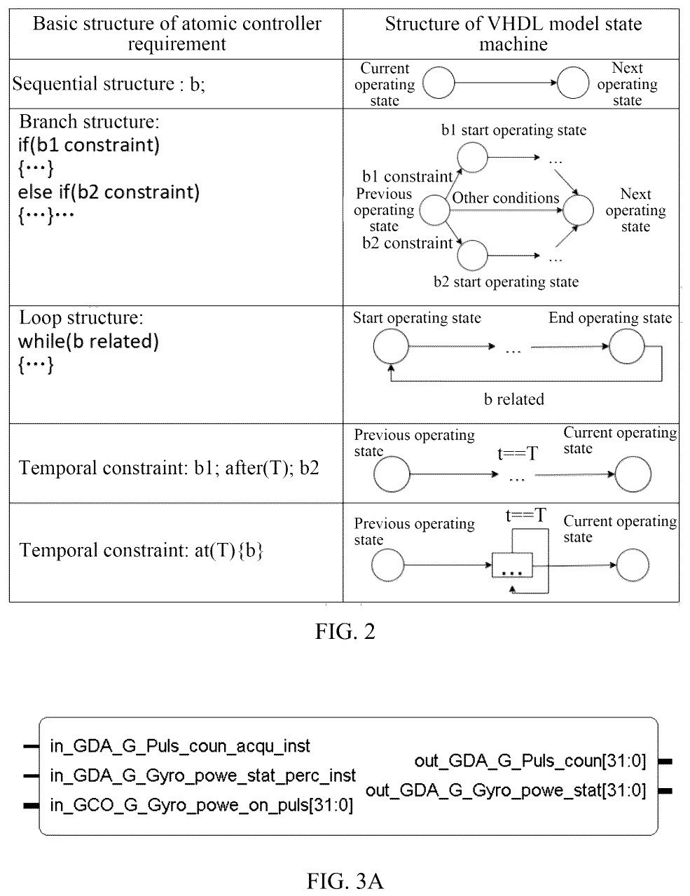

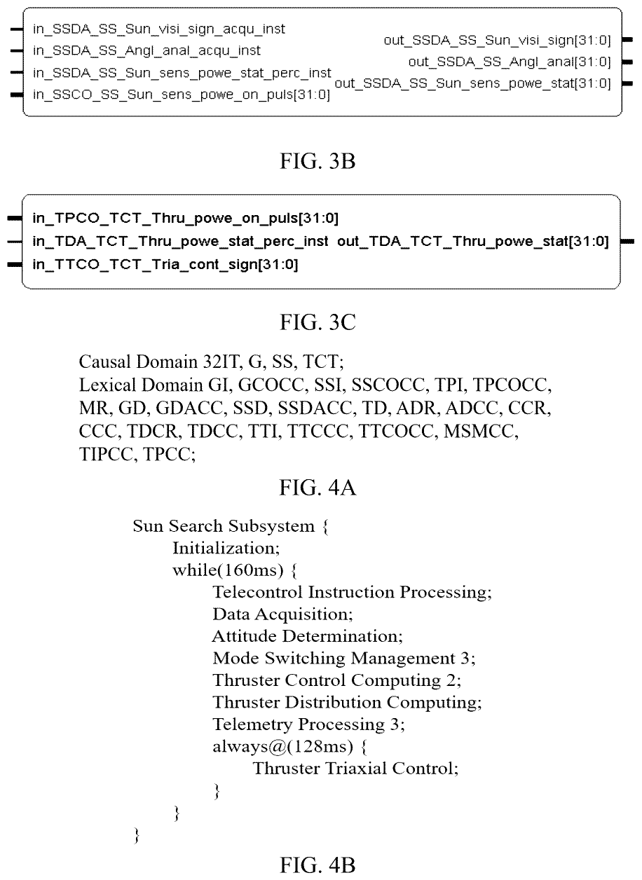

For the sun search system, the devices involved include a gyroscope, a sun sensor, and a thrust. To model these devices, it is first necessary to know whether the device is a sensor or an actuator. The gyroscope and the sun sensor are the sensor, and the thrust is the actuator. FIG. 3A provides a VHDL model of a gyroscope device, the gyroscope interacts with a controller through channels “Gyropoweronsignal” and “Gyropoweroffsignal” for switching an on/off operating state, and detected external environment attributes “Pulsecount” and “Gyropowerstate” are updated through channels “PulsecountacqIns” and “GyropowerstateperIns”. FIG. 3B provides a VHDL model of a sun sensor, the sun sensor interacts with the controller through channels “Sunsensorpoweronsignal” and “Sunsensorpoweroffsignal” for switching an on/off operating state, and detected external environment variables “Sunvisiblesign”, “Sunmeasurementangle” and “Sunsensorpowerstate” are through updated channels “SunvisiblesignacqIns”, “SunmeasurementangleacqIns” and “SunsensorpowerstateperIns”. FIG. 3C provides a VHDL model of a thrust, the thrust communicates with the controller through channels “Thrusterpoweronsignal” and “Thrusterpoweroffsignal” for switching an on/off operating state, and detected external environment variables “JetInterval” and “Thrusterpowerstate” are updated through channels “JetintervalacqIns” and “ThrusterpowerstateIns”; and a control signal of the thrust is received through a channel “Triaxialcontrolsignal” for jet output to adjust an attitude of a satellite.

3. An entity port declaration of a data storage VHDL model is generated according to the atomic controller requirement in the software requirements specification, and a model architecture is supplemented and improved manually.

Names of all data are obtained based on a lexical domain, then behavior interactions in the atomic controller requirement are traversed. If a device is involved in a behavior interaction, the content of the behavior interaction is added with names of a sender and a receiver and then abbreviated to get a port name, such as “in_GDA_G_Puls_coun”, and then the port name is added to the entity port declaration of the data storage VHDL model.

4. A composite controller model is generated according to composite controller requirements in the software requirements specification.

A composite controller VHDL model is generated according to a software requirements specification of the composite controllers. There are 7 composite controllers in the sun search system. FIG. 4B to FIG. 4C provide a comprehensive composite controller requirement and a data acquisition composite controller requirement in a software requirements specification of the sun search system, respectively.

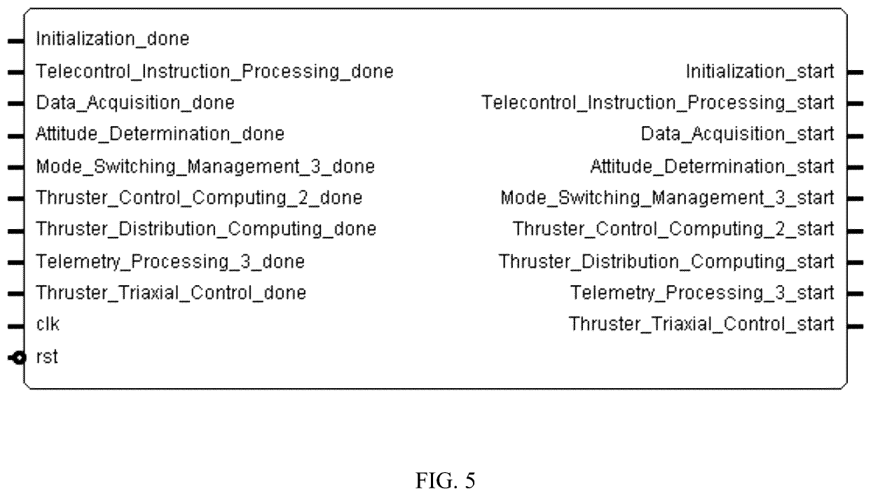

The software requirements specification of the comprehensive composite controller in the sun search system in FIG. 4B is not called by other composite controllers. The generated composite controller VHDL model is as shown in FIG. 5. As this composite controller VHDL model is not called by other controllers, there is no need to add an initial state and an end state to receive a scheduling synchronization signal. Then, the interaction content of the called controller is processed. First, for the sequential structure, “Initialization” (see FIG. 4B) is called, a new operating state “Initialization” is added, and a call signal is added to the operating state, where the call signal “initialization_start” is named with the name of the composite controller to be called plus a field “_start”, a transition from this state to the next state and a synchronization signal “Initialization_done” in the transition constraint are added. According to the requirements specification (see FIG. 4B), there is a loop “while (160 ms)” after the sequential structure, and the loop has a loop structure as shown in FIG. 2. A VHDL model structure corresponding to the loop structure is required to record a loop start state at first, namely, a start state “Telecontrol InstructionProcessing”, then process the interaction behaviors in the loop structure, which is the sequential structure. According to a timed automaton model structure corresponding to the sequential structure in FIG. 2, a state and a transition are added according to the name of the called controller. The first is “Telecontrol Instruction Processing”, an operating state named with the same is added, and a call signal is added in the operating state, where the call signal “Initialization_start” is named with the name of the composite controller to be called plus a field “_start”, a transition from this state to the next state and a synchronization signal “Initialization_done” in the transition constraint are added. The subsequently called controller requirements are processed in the same way. After the last called controller in the loop structure is processed, the end state is reached, a transition back to the initial state is added, and a related guard condition “t==160” is added on the transition. According to the comprehensive composite controller requirement in the sun search system, the generated composite controller model is finally obtained without its own interaction portion.

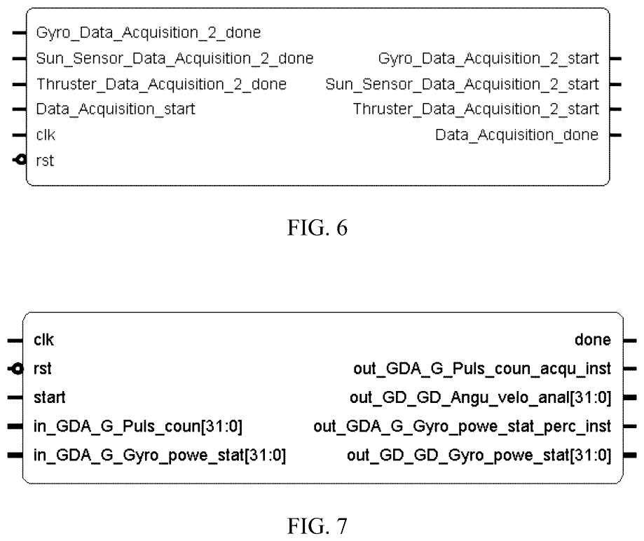

The data acquisition composite controller in FIG. 4C is called by the controller. An initial state and an end state are established at first to cope with the calling of other composite controllers. In the initial state, an operating state signal is Data Acquisition_done=‘0’, indicating that the composite controller VHDL model does not operate; when starting an operating signal Data Acquisition_start=‘1’, the state is transitioned to the operating state, and the composite controller VHDL model starts to operate. In the end state, an operating state signal is Data Acquisition_done=‘1’, indicating that the composite controller VHDL model has completed the operation, and the state is transitioned to the initial state. Then, the interaction action of the called controller is processed. In the sequential structure, Gyro Data Acquisition 2 is called, a new operating state “Gyro Data Acquisition 2” is added, and a call signal is added in the operating state, where the call signal “Gyro data Acquisition 2_start” is named with the name of the composite controller to be called plus a field “_start”, and then a transition from this state to the next state and a synchronization signal “Gyro Data Acquisition 2_done” in the transition constraint are added. The subsequently called controller requirements are processed in a same way, and the generated composite controller model is as shown in FIG. 6.

5. At a phase of system combination, the generated composite controller VHDL model, atomic controller VHDL model, data storage VHDL model and device VHDL model are combined to obtain a complete system model.

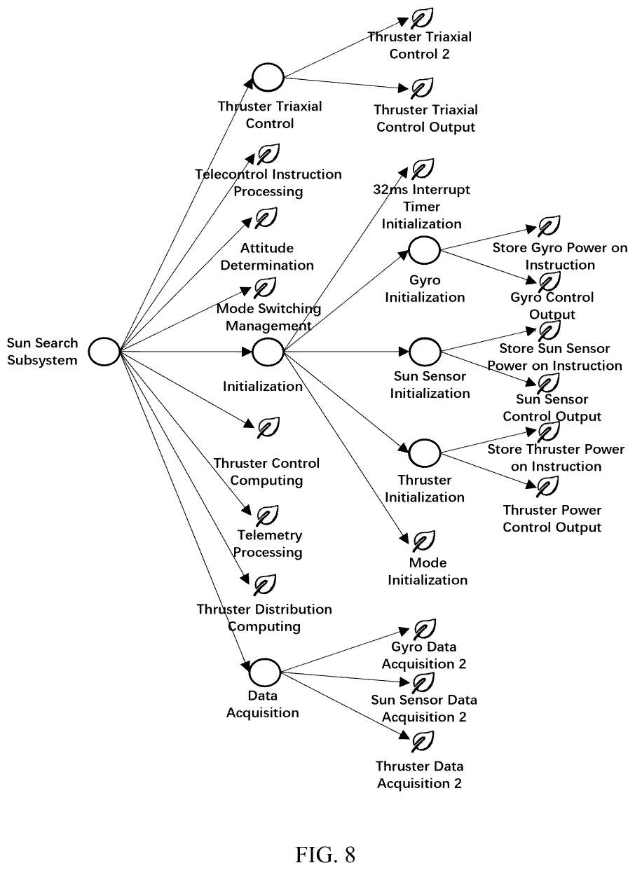

Firstly, a system structure tree is generated according to the names of the composite controllers and a relationship thereof in the composite controller requirements. Each subtree in the structure tree is a subsystem, each non-leaf node is a composite controller, and each leaf node is an atomic controller. The system structure tree of the sun search control software is shown in FIG. 8. The structure tree is traversed from bottom to top, when a non-leaf node is encountered, the composite controller VHDL model of the non-leaf node is combined with other controller VHDL models of its child nodes to obtain a preliminary VHDL model of the system.

Then, according to the names of data storages and the call signals to the data storages involved in the atomic controller requirements, a system software VHDL model is obtained by combining the preliminary VHDL model of the system obtained in the previous step with the data storage VHDL model through same-named port connection.

Finally, according to the names of the devices and the call signals to the devices involved in the atomic controller requirements, a complete system model is obtained by combining the system software VHDL model obtained in the previous step with the device VHDL model through same-named port connection.

6. At a phase of property verification, a property to be verified is formulated according to different property formulation styles, and Vivado is used for simulation and property verification.

Property verification is performed after a requirement simulation model is generated, and the properties are divided into the following types for verification.

For correctness of data flow, whether the system meets a data correctness requirement defined in the software requirements specification when processing data is verified, including checking correct transfer, conversion, calculation, storage and like of the data.

For correctness of control flow, whether the system operates according to a function of the software requirements specification is verified, including checking whether the system correctly executes the required calculation, control and communication function or not.

For satisfiability of temporal constraint, whether a complex embedded system with a temporal constraint completes a corresponding action within a specified time is verified.

In this embodiment, a complete system model is obtained by combining the generated atomic controller VHDL model, device VHDL model, data storage VHDL model and composite controller VHDL model, and an automatic generation process of the simulation model can be implemented. Then, Vivado tool is called for property verification, thereby achieving automatic generation and property verification of a requirement simulation model.

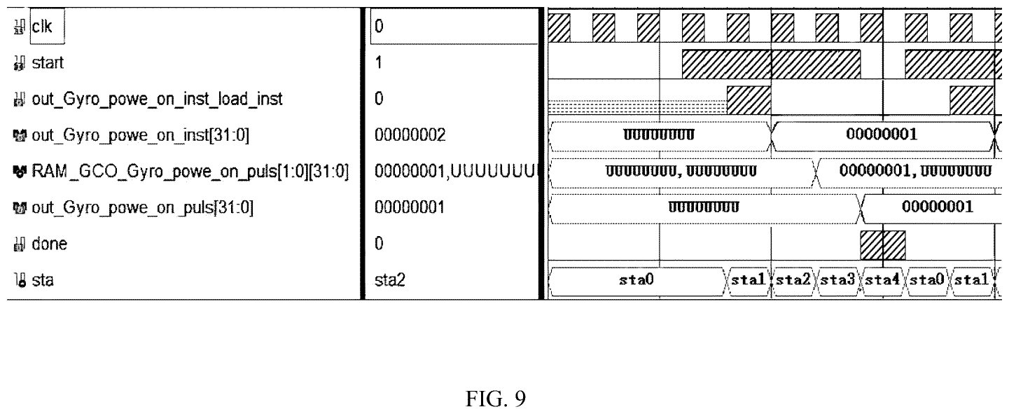

Simulation effect is as follows. Specific details of gyroscope control output atomic problem during sun search are as follows: a machine domain (Gyroscope Control Output Atomic Controller, GCO) sends a read instruction to obtain a gyroscope power-on instruction from gyroscope instruction storage (Gyroscope Instruction Storage, GI), and forwards the power-on instruction to a computing component (Gyroscope Control Output Computing Component, GCOCC) which converts the gyroscope the power-on instruction to obtain a gyroscope power-on signal and forwards the gyroscope power-on signal to the machine domain (GCO), and the machine field (GCO) sends the power-on signal to the gyroscope (G) to complete power-on of the gyroscope. A simulation waveform diagram of a gyroscope control output atomic controller VHDL model is as shown in FIG. 9, a waveform diagram of generated code is explained as follows: a left side of the waveform diagram is a name of the signal, and a right side is a waveform of the signal. The waveform diagram sequentially includes a clock signal (clk), a start signal (GCO_start), a gyroscope power-on instruction read instruction (out_GCO_GI_Gyro_powe_on_inst_load_inst), a gyroscope power-on instruction (out_GCO_GCOC_Gyro_powe_on_inst), a gyroscope power-on signal memory (RAM_GCO_Gyro_powe_on_puls), a gyroscope power-on signal (out_GCO_G_Gyro_powe_on_puls), a completion signal (GCO_done) and a state signal (sta) from top to bottom.

First state (sta0), this state means standby for initiation, the atomic component does not operate and has no output signal, and as shown in FIG. 9, the waveform of the signal is in an unknown state. The first state is transitioned to a second state (sta1) upon the next rising edge of the clock after the start signal transitions to a high level.

At the second state (sta1), the gyroscope power-on read instruction transitions to the high level, and the second state is transitioned to a third state (sta2) upon the next rising edge of the clock.

At the third state (sta2), the gyroscope power-on instruction output to a computing subcomponent becomes valid (00000001), and the third state is transitioned to the fourth state (sta3) upon the next rising edge of the clock.

At the fourth state (sta3), the gyroscope power-on signal sent by the computing subcomponent becomes valid (00000001), and the fourth state is transitioned to a fifth state (sta4) upon the next rising edge of the clock.

At the fifth state (sta4), the gyroscope power-on signal output to the gyroscope becomes valid (00000001) and the completion signal transitions to the high level, and the fifth state is transitioned to the first state (sta0) upon the next rising edge of the clock.

In the property verification aspect, the verification result is as follow. With respect to consistency of data flow, there are 263 interfaces, 261 of which are successful in consistency constraint verification, leading to the failure of consistency constraint verification of two interfaces. Two interfaces in MR (mode record) data storage are failed in verification. With respect to correctness of control flow, for 19 atomic problems and 7 composite problems, the 19 atomic problems are all successful in control flow verification, 6 composite problems are successful in control flow verification, and one composite problem is failed in control flow verification. With respect to temporal constraint, a periodic loop constraint of 160 ms is successful in verification, and a temporal constraint for scheduled triggering of a jet control signal at 128 ms is successful in verification. For satisfiability of temporal constraint, a temporal constraint for scheduled triggering of a jet control signal at an interval of 128 ms in the sun search control software is successful in verification, and a periodic loop constraint of 160 ms in the sun search control software is successful in verification. For correctness of data flow, there are 263 interfaces in the sun search control software, where a shared phenomenon conflict on current mode word between a remote-control atomic problem and a mode-switching atomic problem has triggered failures in two consistency constraint verifications. For correctness of control flow, there are 19 atomic problems in the sun search control software, and a control flow constraint is verified successfully; there are 7 control dependences in the sun search control software, where a while loop time constraint of a main control dependence is not bound to a 32 ms timer, making the control flow constraint verification failed.

Various embodiments in this specification are described in a progressive way, and each embodiment focuses on the differences from other embodiments, so it is only necessary to refer to the same and similar parts between the embodiments. As the system disclosed by the embodiments corresponds to the method disclosed by the embodiments, the description is relatively simple, and the reference is made to the descriptions in the method for related parts.

According to the foregoing description of the disclosed embodiments, those skilled in the art can implement or practice the present disclosure. Various modifications to these embodiments are apparent to those skilled in the art, the general principles defined herein may be implemented in other embodiments without departing from the spirit and scope of the present disclosure. Hence, the present disclosure is not limited to the embodiments disclosed herein, but is to conform to the widest scope in accordance with the principles and novel features disclosed herein.

1. A Very-High-Speed Integrated Circuit Hardware Description Language (VHDL)-based semi-automatic simulation method for software requirements of a complex embedded system, comprising:
pre-defining a domain-specific device model, wherein the device model is a manually constructed device VHDL model;
generating an atomic controller VHDL model according to atomic controller requirements in a software requirements specification, and manually supplementing and improving computing components in the atomic controller VHDL model;
generating a data storage VHDL model according to the atomic controller requirements in the software requirements specification;
generating a composite controller VHDL model according to composite controller requirements in the software requirements specification;
at a phase of system combination, combining the atomic controller VHDL model, the device VHDL model, the data storage VHDL model and the composite controller VHDL model generated, to obtain a complete system model; and
at a phase of property verification, performing property verification on the complete system model by using a VHDL verification tool Vivado.

2. The VHDL-based semi-automatic simulation method for the software requirements of the complex embedded system according to claim 1, wherein the generating an atomic controller VHDL model and the manually supplementing and improving computing components comprise following steps:
traversing the atomic controller requirements in the software requirements specification to obtain names of atomic controllers, the computing components, devices and data storages involved in the atomic controller requirements;
generating a model structure of the atomic controller VHDL model according to the names of the atomic controllers and the names of the computing components in the atomic controller requirements;
generating an entity port declaration of the atomic controller VHDL model according to the names of the devices and call signals to the devices involved in the atomic controller requirements, the names of the data storages and call signals to the data storages involved in the atomic controller requirements, the names of the computing components and call signals to the computing components involved in the atomic controller requirements;
generating an initial state and an end state of the atomic controller VHDL model based on a relationship between the atomic controller requirements and the composite controller requirements, and generating a state machine process of the atomic controllers by combining a sequence of call signals of the atomic controller requirements to the devices, the data storages and the computing components;
generating signals and variables used in the atomic controller VHDL model according to a description of shared phenomena in the atomic controller requirements; and
manually supplementing and improving the computing components in the generated atomic controller VHDL model.

3. The VHDL-based semi-automatic simulation method for software requirements of the complex embedded system according to claim 1, wherein the generating a data storage VHDL model comprises:
generating an entity port declaration of the data storage VHDL model according to the names of the data storages and the call signals to the data storages involved in the atomic controller requirements.

4. The VHDL-based semi-automatic simulation method for the software requirements of the complex embedded system according to claim 1, wherein the generating a composite controller VHDL model comprises following steps:
generating an entity port declaration of the composite controller VHDL model according to names of composite controllers in the composite controller requirements;
generating a state of the composite controller VHDL model according to the names of the composite controllers and a relationship thereof in the composite controller requirements; and
generating a transition condition between corresponding states according to a temporal constraint on the composite controllers in the composite controller requirements.

5. The VHDL-based semi-automatic simulation method for the software requirements of the complex embedded system according to claim 1, wherein the obtaining a complete system specifically comprises following steps:
generating a system structure tree according to names of composite controllers and a relationship thereof in the composite controller requirements, and traversing the structure tree from bottom to top to combine the composite controller VHDL model and the atomic controller VHDL model;
combining the model obtained by combining in a previous step with the data storage VHDL model according to the names of the data storages and the call signals to the data storages involved in the atomic controller requirements; and
combining the model obtained by combining in a previous step with the device VHDL model according to the names of the devices and the call signals to the devices involved in the atomic controller requirements to obtain the complete system model.

6. The VHDL-based semi-automatic simulation method for the software requirements of the complex embedded system according to claim 1, wherein at the phase of property verification, a property type to be verified and a property capable of being verified by Vivado comprise:
correctness of data flow, verifying whether the system meets a data correctness requirement defined in the software requirements specification when processing data;
correctness of control flow, verifying whether the system operates according to a function of the software requirements specification; and
satisfiability of temporal constraint, verifying whether a complex embedded system with a temporal constraint completes a corresponding action within a specified time.

7. The VHDL-based semi-automatic simulation method for the software requirements of the complex embedded system according to claim 6, wherein verification of the satisfiability of temporal constraint comprises following three main types:
(1) verifying entry into state X at a specific time to: A< >X imply t==t₀;
(2) with a task T as a periodic task of a period of p, assuming that a clock t is specifically used to record an execution time of the task, verifying whether the execution time meets the period: A< >T.init imply t==p, wherein T.init represents an init state node of a timed automaton model T; and
(3) verifying whether a time interval in which the state X is maintained is [t₁, t₂]: A< >X imply t>=t₁&&t<=t₂.

8. A VHDL-based semi-automatic simulation system for software requirements of a complex embedded system for implementing the method according to claim 1, comprising a device predefining module, an atomic controller generation module, a data storage generation module, a composite controller generation module, a system combination module, and a property verification module, wherein
the device predefining module is configured to pre-define the domain-specific device model, wherein the device model is the manually constructed device VHDL model;
the atomic controller generation module is configured to generate the atomic controller VHDL model according to the atomic controller requirements in a software requirements specification, and manually supplement and improve the computing components in the atomic controller VHDL model;
the data storage generation module is configured to generate the data storage VHDL model according to the atomic controller requirements in the software requirements specification;
the composite controller generation module is configured to generate the composite controller VHDL model according to the composite controller requirements in the software requirements specification;
the system combination module is configured to combine the atomic controller VHDL model, the device VHDL model, the data storage VHDL model and the composite controller VHDL model generated, to obtain the complete system model; and
the property verification module is configured to perform the property verification on the complete system model by using the VHDL verification tool Vivado.

9. The VHDL-based semi-automatic simulation system for software requirements of the complex embedded system for implementing the method according to claim 8, wherein the atomic controller generation module is configured to:
traverse the atomic controller requirements in the software requirements specification to obtain names of atomic controllers, the computing components, devices and data storages involved in the atomic controller requirements;
generate a model structure of the atomic controller VHDL model according to the names of the atomic controllers and the names of the computing components in the atomic controller requirements;
generate an entity port declaration of the atomic controller VHDL model according to the names of the devices and call signals to the devices involved in the atomic controller requirements, the names of the data storages and call signals to the data storages involved in the atomic controller requirements, the names of the computing components and call signals to the computing components involved in the atomic controller requirements;
generate an initial state and an end state of the atomic controller VHDL model based on a relationship between the atomic controller requirements and the composite controller requirements, and generate a state machine process of the atomic controllers by combining a sequence of call signals of the atomic controller requirements to the devices, the data storages and the computing components;
generate signals and variables used in the atomic controller VHDL model according to a description of shared phenomena in the atomic controller requirements; and
manually supplement and improve the computing components in the generated atomic controller VHDL model.

10. The VHDL-based semi-automatic simulation system for software requirements of the complex embedded system for implementing the method according to claim 8, wherein the data storage generation module is configured to:
generate an entity port declaration of the data storage VHDL model according to the names of the data storages and the call signals to the data storages involved in the atomic controller requirements.

11. The VHDL-based semi-automatic simulation system for software requirements of the complex embedded system for implementing the method according to claim 8, wherein the composite controller generation module is configured to:
generate an entity port declaration of the composite controller VHDL model according to names of composite controllers in the composite controller requirements;
generate a state of the composite controller VHDL model according to the names of the composite controllers and a relationship thereof in the composite controller requirements; and
generate a transition condition between corresponding states according to a temporal constraint on the composite controllers in the composite controller requirements.

12. The VHDL-based semi-automatic simulation system for software requirements of the complex embedded system for implementing the method according to claim 8, the system combination module is configured to:
generate a system structure tree according to names of composite controllers and a relationship thereof in the composite controller requirements, and traverse the structure tree from bottom to top to combine the composite controller VHDL model and the atomic controller VHDL model;
combine the model obtained by combining in a previous step with the data storage VHDL model according to the names of the data storages and the call signals to the data storages involved in the atomic controller requirements; and
combine the model obtained by combining in a previous step with the device VHDL model according to the names of the devices and the call signals to the devices involved in the atomic controller requirements to obtain the complete system model.

13. The VHDL-based semi-automatic simulation system for software requirements of the complex embedded system for implementing the method according to claim 8, the property verification module is configured to:
for correctness of data flow, verify whether the system meets a data correctness requirement defined in the software requirements specification when processing data;
for correctness of control flow, verify whether the system operates according to a function of the software requirements specification; and
for satisfiability of temporal constraint, verify whether a complex embedded system with a temporal constraint completes a corresponding action within a specified time.

14. The VHDL-based semi-automatic simulation system for software requirements of the complex embedded system for implementing the method according to claim 13, wherein verification of the satisfiability of temporal constraint comprises following three main types:
(1) verifying entry into state X at a specific time to: A< >X imply t==t₀;
(2) with a task T as a periodic task of a period of p, assuming that a clock t is specifically used to record an execution time of the task, verifying whether the execution time meets the period: A< >T.init imply t==p, wherein T.init represents an init state node of a timed automaton model T; and
(3) verifying whether a time interval in which the state X is maintained is [t₁, t₂]: A< >X imply t>=t₁&&t<=t₂.
